(19) United States
(12) Patent Application Publication
(10) Pub. No.: US 2009/0322326 A1
(43) Pub. Date: Dec. 31, 2009

(54) Magnetic field probe, current distribution measuring device and radio device

(75) Inventors: Takayoshi Ito, Yokohama-Shi (JP); Tetsuro Itakura, Tokyo (JP); Shuichi Obayashi, Yokohama-Shi (JP)

Correspondence Address: NIXON & VANDERHYE, PC, 901 NORTH GLEBE ROAD, 11TH FLOOR, ARLINGTON, VA, 22203, US

(73) Assignee: KABUSHIKI KAISHA TOSHIBA, Tokyo (JP)

(21) Appl. No.: 12/379,250

(22) Filed: Feb. 17, 2009

(30) Foreign Application Priority Data
Jun. 27, 2008 (JP) 2008-169215

(51) Int. Cl. G01R 33/00

(52) U.S. Cl. 324/263

(57) ABSTRACT

There is provided a magnetic field probe which includes: a probe body which is a coaxial cable wound to form a plurality of loop-like portions in planar view, the coaxial cable including an inner conductor, an insulator enclosing the inner conductor and an outer conductor enclosing the insulator; and a plurality of notches each of which is formed in each of the loop-like portions so that the outer conductor is divided to expose the inner conductor or the insulator, wherein: a plurality of outer conductor parts resulting from division by the notches are arranged to be electrically connected to each other, an one end of the inner conductor in the coaxial cable is connected to any one of the outer conductor parts; and winding directions of at least one of a pair of loop-like portions among the loop-like portions are reversed from each other in planar view.

### CROSS REFERENCE TO RELATED APPLICATIONS

This application is based upon and claims the benefit of priority from the prior Japanese Patent Applications No. 2008-169215, filed on Jun. 27, 2008; the entire contents of which are incorporated herein by reference.

### BACKGROUND OF THE INVENTION

1. Field of the Invention

The present invention relates to a magnetic field probe for measuring magnetic fields, and to a current distribution measuring device and a radio device using the magnetic field probe.

2. Related Art

Magnetic field probes are purposed to measure current distribution on a substrate. As such magnetic field probes, shielded loop probes are known, which are unlikely to take influence from electric fields. Shielded loop probes known recently use multi-layer substrate to downsize and sensitize the probes, as disclosed in JP-A2007-101330 (Kokai).

In the prior art document mentioned above, when a probe is set up so that the loop thereof is parallel to the substrate, and measurement is carried out right above the signal line through which current passes, induction currents mutually cancel each other to minimize the magnetic field to be measured. Thus, there has been a problem that indication of the measurement results only on a graph could not take away the difficulty of understanding the current distribution. Also, there has been another problem that the conventional probe is likely to receive undesired magnetic fields that have traveled from a long distance to disable accurate estimation of the desired current right beneath the probe.

### SUMMARY OF THE INVENTION

According to a first aspect of the present invention, there is provided with a magnetic field probe comprising:

a probe body which is a coaxial cable wound to form a plurality of loop-like portions in planar view, the coaxial cable including an inner conductor, an insulator enclosing the inner conductor and an outer conductor enclosing the insulator; and

a plurality of notches each of which is formed in each of the loop-like portions so that the outer conductor is divided to expose the inner conductor or the insulator, wherein:

a plurality of outer conductor parts resulting from division by the notches are arranged to be electrically connected to each other,

an one end of the inner conductor in the coaxial cable is connected to any one of the outer conductor parts; and

winding directions of at least one of a pair of loop-like portions among the loop-like portions are reversed from each other in planar view.

According to a second aspect of the present invention, there is provided with a magnetic field probe comprising:

a multi-layer substrate including a lower layer substrate, a middle layer substrate and an upper layer substrate;

a signal line formed at a surface of the middle layer substrate, wherein the signal line includes a plurality of first loop-like portions each having an opening and being serially connected via an one end or both ends of each of the first loop-like portions, and at least one of a pair of loop-like portions among the first loop-like portions have winding directions which are reversed from each other in planar view when a path of the signal line is followed from one end of the signal line to the other end of the signal line, or vice versa.;

a first ground line formed at a surface of the upper layer substrate so as to go along the signal line in planer view, wherein the first ground line has second loop-like portions corresponding to the first loop-like portions in planer view, each of the second loop-like portions has a first notch formed to divide the first ground line to expose a surface of the upper layer substrate, and the first ground line has a first joint which electrically connects between lines resulting from division by each first notch, via a position different from that of the first notch;

a second ground line formed at a surface of the lower layer substrate so as to go along the signal line, wherein the second ground line has third loop-like portions corresponding to the first loop-like portions in planer view, each of the third loop-like portions has a second notch to divide the second ground line to expose a surface of substrate at a position corresponding to the first notch in planer view, and the second ground line has a second joint which electrically connects between lines resulting from division by each second notch, via a position different from that of the second notch; and

a through hole formed in the multi-layer substrate which connects the one end of the signal line to the first and the second ground lines electrically.

According to a third aspect of the present invention, there is provided with a current distribution measuring device which measures current distribution on a substrate, comprising:

a magnetic field probe according to the first aspect of the present invention;

a scanning device configured to scan a surface of the substrate by using the magnetic field probe; and

a reading unit configured to read induction current produced at the magnetic field probe depending on magnetic fields generated in the substrate.

According to an aspect of the present invention, there is provided with a radio device provided in an electronic device including a noise source, comprising:

an antenna configured to receive signals;

the magnetic field probe according to the first aspect of the present invention, which is provided for the noise source and produces induction current depending on magnetic fields generated at the noise source;

a noise cancellation unit configured to cancel noise components which have mixed into received signals of the antenna, by subtracting components of the produced induction current from the received signals; and

a signal processor configured to process the received signals after nose cancellation.

### BRIEF DESCRIPTION OF THE DRAWINGS

FIGS. 1A and 1B are schematic diagrams illustrating a magnetic field probe according to a first embodiment;

FIGS. 2A and 2B are explanatory views illustrating the state of a magnetic field above a microstrip line;

FIGS. 3A and 3B are explanatory views illustrating the principle of operation of the electric field probe illustrated in FIGS. 1A and 1B for an arced electric field;

FIGS. 4A and 4B illustrate an example where a winding method of a coaxial cable has been changed in the magnetic field probe illustrated in FIGS. 1A and 1B;

FIG. 5 illustrates an example where a part of the coaxial cable has been substituted by a copper rod in the magnetic field probe illustrated in FIGS. 1A and 1B;

FIGS. 6A to 6C are schematic diagrams illustrating the magnetic field probe of FIGS. 1A and 1B, with an addition of balun function;

FIGS. 7A and 7B are schematic diagrams illustrating the magnetic field probe of FIGS. 1A and 1B, with an increase of the number of loops;

FIG. 8 is a schematic diagram illustrating a configuration (configuration of a multi-layer substrate) of a magnetic field probe according to a second embodiment;

FIG. 9 is an exploded view illustrating layers of the multi-layer substrate illustrated in FIG. 8;

FIGS. 10A to 10C are schematic diagrams illustrating a configuration (spatial configuration) of a magnetic field probe according to a third embodiment;

FIG. 11 illustrates a modification of the magnetic field probe illustrated in FIGS. 10A to 10C;

FIG. 12 illustrates a problem of the magnetic field probe according to the first embodiment;

FIG. 13 is a schematic diagram illustrating a magnetic field probe according to a fourth embodiment;

FIG. 14 is a schematic diagram illustrating a current distribution measuring device using the magnetic field probe of the present invention;

FIG. 15 illustrates an example of another configuration of a current distribution measuring device;

FIG. 16 illustrates an example of still another configuration of a current distribution measuring device;

FIG. 17 is a schematic diagram illustrating a radio device incorporating a noise cancelling device using the magnetic field probe of the present invention;

FIGS. 18A and 18B are explanatory views illustrating the principle of operation of the magnetic field probe of the present invention for magnetic fields that have traveled over a long distance;

FIG. 19 is a schematic view illustrating a laptop computer incorporating a noise cancelling device using the magnetic field probe of the present invention; and

FIGS. 20A and 20B are schematic diagrams illustrating a conventional magnetic field probe.

### DETAILED DESCRIPTION OF THE INVENTION

With reference to the drawings, hereinafter will be described in detail some embodiments of the present invention.

### First Embodiment

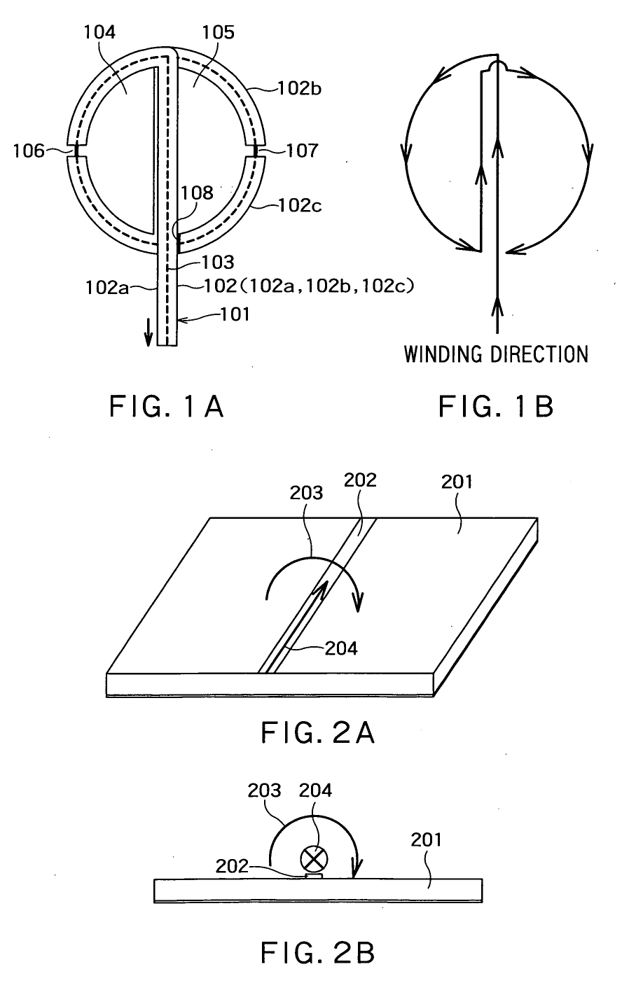

Referring to FIGS. 1A to 7B, hereinafter is described a first embodiment of the present invention.

FIG. 1A is a schematic diagram illustrating a magnetic field probe according to the first embodiment of the present invention. FIG. 1B illustrates the winding direction of the magnetic field probe illustrated in FIG. 1A.

In FIG. 1A, a coaxial cable 101 consisting of an inner conductor 103, an insulator enclosing the inner conductor 103, and an outer conductor 102 enclosing the insulator, is wound so as to form a plurality of loop-like portions (a loop-like portion is just referred to as “loops” simply hereinafter) 104 and 105 isolated from each other in planar view. A plurality of slits (notches) 106 and 107 are formed in respective portions of the plurality of loops 104 and 105. The slits divide the outer conductor 102 to expose the inner conductor 103 or the insulator. Here, the inner conductor 103 is exposed.

The inner conductor 103 at one end 108 of the coaxial cable 101 is connected to any of outer conductor parts 102a to 102c divided by the plurality of slits. Here, the inner conductor 103 at the end 108 is connected to the outer conductor part (first outer conductor part) 102a on the side of the other end of the coaxial cable 101.

Also, the outer conductor parts 102a to 102c divided by the plurality of slits are electrically connected to each other to keep the symmetric property of the outer conductor. This can provide a balun structure where current is not passed, or is unlikely to be passed, through the outer conductor in the axial direction (refer to the arrow indicated in FIG. 1A) in which the end of the coaxial cable 101 opposite to the end 108 extends. In the example shown in the figure, the outer conductor at the end 108 of the coaxial cable 101 (the outer conductor part 102c on the side of the end 108) is connected to the outer conductor part (first outer conductor part) 102a on the side of the end of the coaxial cable 101 opposite to the end 108. Also, the outer conductor part (third outer conductor part) 102b sandwiched between two slits is connected to the first outer conductor part 102a in the vertical direction as viewed in the figure. In this way, the outer conductor parts 102a to 102c are electrically connected to each other.

As shown in FIG. 1B, the winding direction of the loop 104 in planar view is reversed from the winding direction of the loop 105. In other words, the winding direction of the loop 104 is counterclockwise and that of the loop 105 is clockwise.

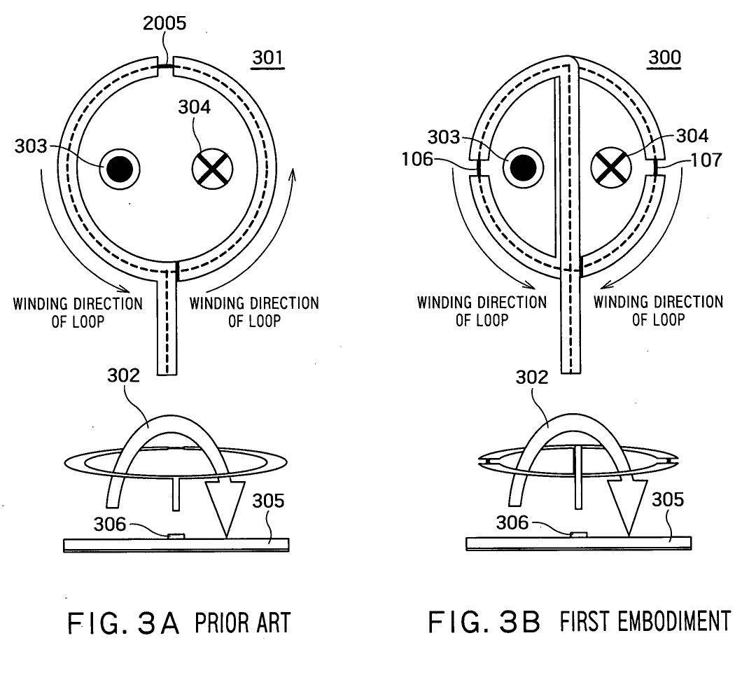

Referring to FIGS. 2A to 3B, the operation of the magnetic field probe shown in FIGS. 1A and 1B is described.

FIG. 2A illustrates a magnetic field 203 which is produced by current 204 that passes a microstrip line 202 on a substrate 201. As shown in FIG. 2B, the current passing on the microstrip line 202 produces a magnetic field, drawing an arc around the current, according to the right-handed screw rule. Generally, magnetic field probes are used for measuring magnetic fields in the vicinity of such a current source. Hence, description hereinafter is focused on arced magnetic fields, as objects to be measured.

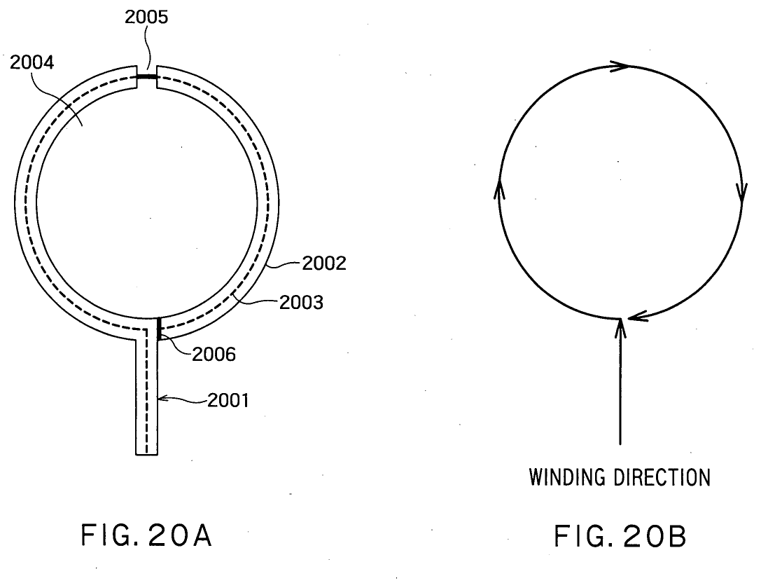

FIGS. 3A and 3B are explanatory views illustrating differences in the operation for an arced magnetic field, between a conventional probe 301 and a proposed probe 300 according to the present embodiment. Each of FIGS. 3A and 3B indicates a relationship between a magnetic field and a loop in the case where the probe is located right above a line 306 on a substrate 305, being opposed to the surface of the substrate. Detailed configuration of the conventional probe 301 is as shown in FIGS. 20A and 20B. A coaxial cable 2001 is wound to form a single loop 2004 in planar view. An outer conductor 2002 and an inner conductor 2003 at one end 2006 are connected to the outer conductor 2002 on the side of the other end. A slit (notch) 2005 is formed at a portion of the coaxial cable 2001 to divide the outer conductor 2002 and expose the inner conductor 2003.

In FIGS. 3A and 3B, a magnetic field 302 is interlinked with loops. In particular, a magnetic field 303 is interlinked with the loops from below, and a magnetic field 304 is interlinked with the loops from above.

In the proposed probe 300 shown in FIG. 3B, the winding direction of the loop with which the magnetic field 303 is interlinked is reversed from the winding direction of the loop with which the magnetic field 304 is interlinked. Accordingly, currents inducted in the loops mutually intensify each other. Specifically, the interlinkage of the magnetic field 303 with the loop on the left side as viewed in the figure permits an electric field to be generated between the outer conductor parts which face with each other via the slit 106. This electric field permits current to flow through the inner conductor in the slit 106. Similarly, the interlinkage of the magnetic field 304 with the loop on the right side as viewed in the figure permits an electric field to be generated between the outer conductor parts which face with each other via the slit 107. This electric field permits current to flow through the inner conductor in the slit 107. The flowing direction is the same between the current that has flowed into the inner conductor in the slit 106 and the current that has flowed into the inner conductor in the slit 107. Accordingly, these currents are added up and the intensified currents are outputted from an end of the coaxial line, which is opposite to an end connected to an outer conductor part of the coaxial cable.

In contrast, in the conventional probe 301 shown in FIG. 3A, since the magnetic fields 303 and 304 of reverse directions are interlinked with the same loop, currents induced to the loop mutually cancel each other. Specifically, in the conventional probe 301, due to the cancellation, no electric field is produced across the outer conductor parts facing each other via the slit 2005. This means that no current passes through the inner conductor in the slit 2005.

As explained above, in the proposed probe 300, the measured values of the magnetic fields right above the current passing through the line 306 can be maximized. Accordingly, the current distribution can be intuitively understood by indicating the measured values on a graph.

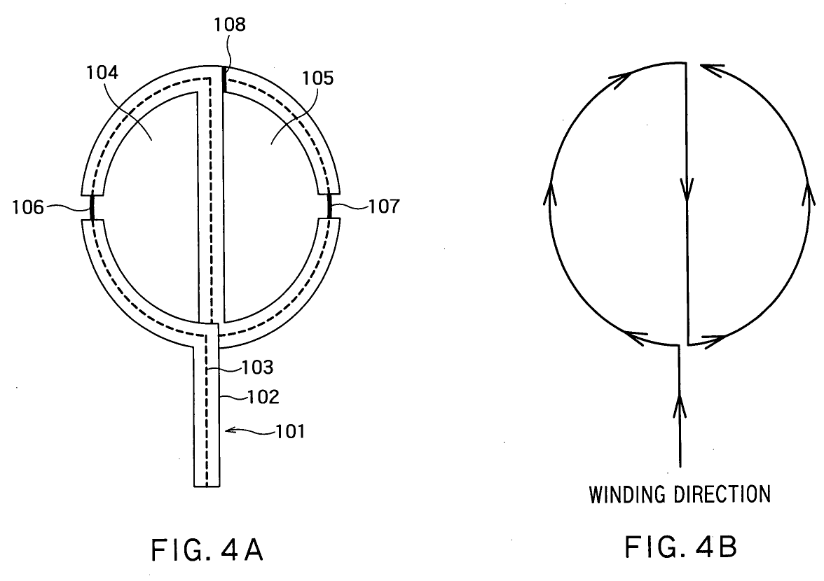

It should be appreciated that FIGS. 1A and 1B show just an example of a method of winding the coaxial cable in a magnetic field probe, and accordingly, the present invention is not limited to this. For example, the two loops may be formed by winding the coaxial cable with the method shown in FIGS. 4A and 4B. FIG. 4A is a top view and FIG. 4B is an illustration showing a winding direction. The parts which are similar to those in FIGS. 1A and 1B are designated with the same reference symbols to omitted detailed explanation.

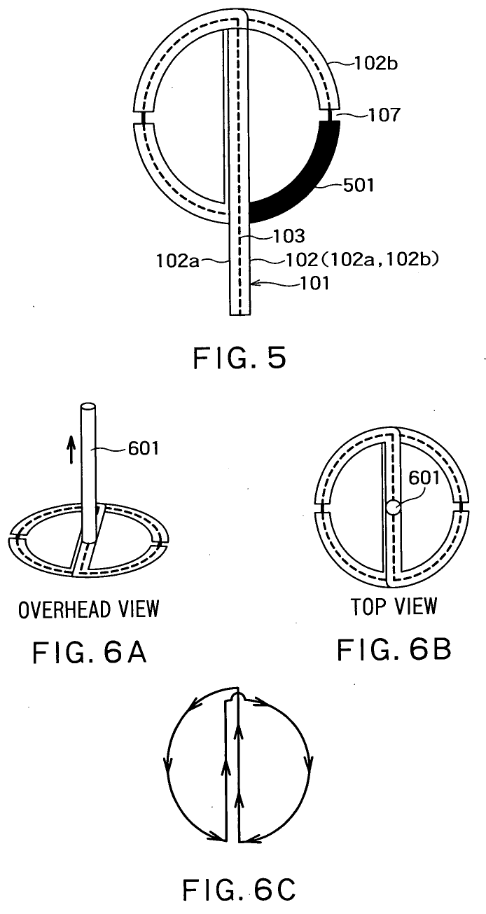

FIG. 5 shows a modification of the magnetic field probe according to the present embodiment.

In FIG. 5, a portion of the coaxial cable 101 shown in FIG. 1A is replaced by a copper rod 501. Specifically, a portion of the coaxial cable 101 from an end thereof up to the nearest slit (slit 107 here) along the coaxial cable 101, is replaced by the copper rod (metal member) 501. One end of the copper rod 501 is connected to the inner conductor 103 and the other end of the copper rod 501 is connected to the first outer conductor part 102a described above. The thickness of the copper rod 501 is the same or substantially the same as that of the coaxial cable 101 to thereby enhance the symmetric property. The advantages equal to the magnetic probe shown in FIGS. 1A and 1B can be obtained by the configuration shown in FIG. 5 as well.

FIGS. 6A to 6C illustrate another modification of the magnetic field probe according to the present embodiment. FIG. 6A is an overhead view, FIG. 6B is a top view and FIG. 6C is an illustration showing a winding direction of the coaxial cable.

As shown in FIG. 6A, the magnetic field probe is disposed, facing the surface to be measure. As shown, the coaxial cable 101 is bent so that an end side of the coaxial cable 101 will be substantially perpendicular to the surface to be measured to provide a shaft (i.e. vertical part) 601. This magnetic field probe has an axisymmetric structure with the shaft 601 as an axis. Such an axisymmetric structure can balance the current passing through the outer conductor to turn the structure into a balun structure where the current on the outer conductor does not pass, or is unlikely to pass, in the axial direction (see the arrow in the figure). The axisymmetric structure can contribute to further enhancing the accuracy of measurement comparing with the structure shown in FIGS. 1A and 1B.

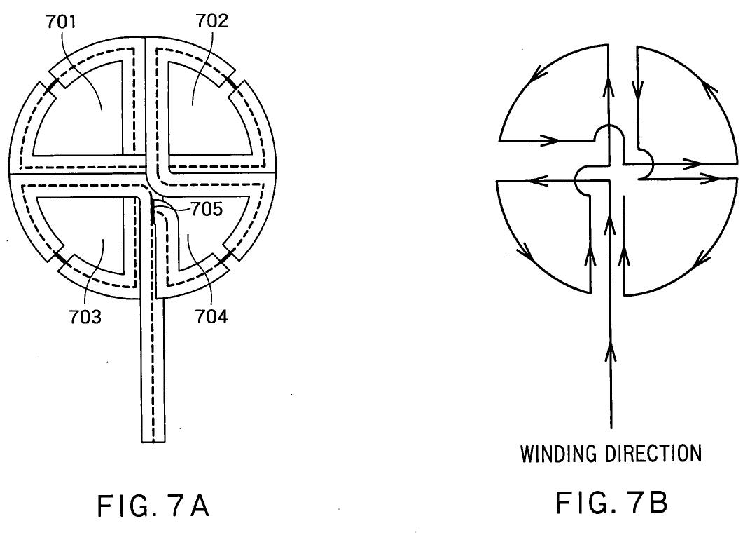

FIGS. 7A and 7B are schematic diagrams illustrating the structure of a magnetic field probe in which the number of loops has been increased to four. FIG. 7A is a top view and FIG. 7B is an illustration showing a winding direction of the coaxial cable.

Loops 701, 702 and 703 are wound counterclockwise and a loop 704 is wound clockwise. In order that the currents induced to the individual loops by arced magnetic fields will not be mutually weakened as a whole, it is necessary, in this way, that the winding directions of at least a pair of loops are reversed from each other. In the example shown in FIGS. 7A and 7B, the winding directions are reversed in each of pairs of the loops 703 and 704 and the loops 704 and 702, for example. When the magnetic field probe shown in the figures is used in the posture as indicated in FIG. 7A, high accuracy can be achieved in the measurement from right above of either of signal lines (not shown) running in the horizontal and vertical directions as viewed in the figure. In other words, when the horizontal signal line as viewed in the figure is measured from above, the induction currents in the pair of loops 702 and 704 mutually intensify each other, and when the vertical signal line as viewed in the figure is measured from above, the induction currents in the pair of loops 703 and 704 mutually intensify each other.

Similar to the configuration shown in FIG. 1A, each of the loops 701 to 704 is formed with a slit (notch) that divides the outer conductor of the coaxial cable to expose the inner conductor or the insulator. The individual outer conductor parts that have been divided by the slits are electrically connected to each other, and the inner connector at an end 705 of the coaxial cable being connected to any of the outer conductor parts.

FIGS. 7A and 7B show an example where the number of loops has been increased to four. Alternative to this, the number of loops may be increased to three or five or more. In these cases as well, the winding directions of at least a pair of loops are required to be reversed from each other.

As described above, according to the present embodiment, the coaxial cable is wound to form a plurality of loops in which the winding directions of at least a pair of loops are reversed from each other in planar view. Thus, when the signal line (current) in a measurement surface is measured from right above, measurement of high sensitivity can be achieved owing to the mutually intensified induction currents which are induced by the at least a pair of loops.

### Second Embodiment

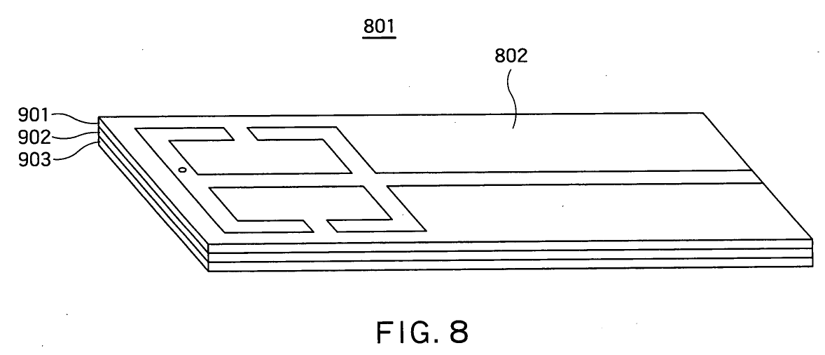

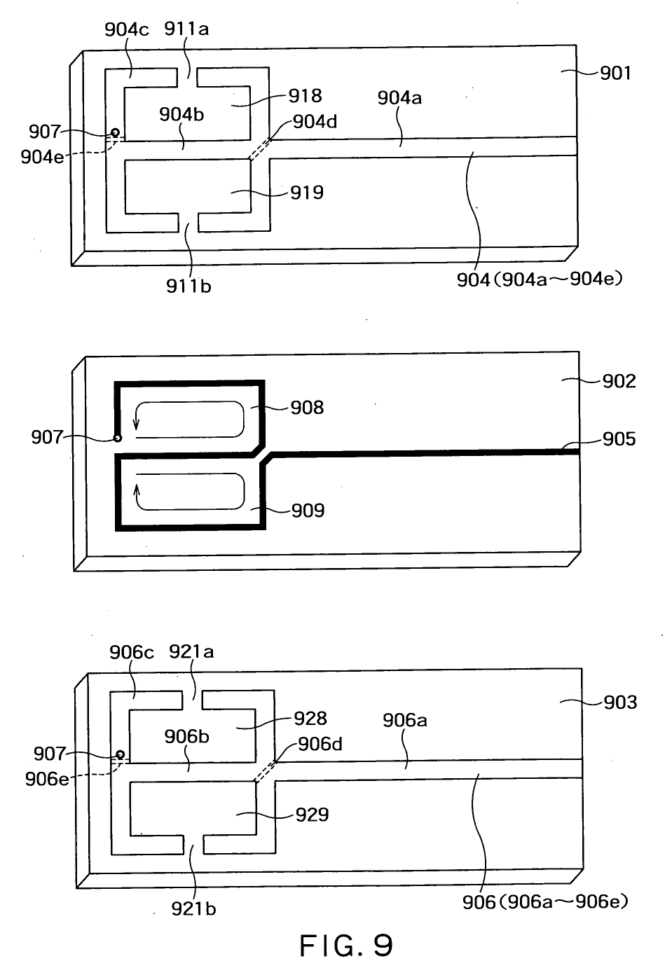

With reference to FIGS. 8 and 9, hereinafter is described a second embodiment of the present invention.

FIG. 8 is a schematic diagram illustrating a magnetic field probe 801 according to the second embodiment. The magnetic field probe 801 is fabricated by using a multi-layer substrate 802 having an upper layer substrate 901, a middle layer substrate 902 and a lower layer substrate 903. FIG. 9 shows the individual substrates 901 to 903 of the magnetic field probe 801 shown in FIG. 8, as disassembled.

Each of the upper, middle and lower layer substrates 901, 902 and 903 is made up of an insulator.

A signal line 905 corresponding to the inner conductor of the coaxial cable is formed at the surface of the middle layer substrate 902. In the signal line 905, a plurality of loop-like portions (hereinafter just referred to as “loops”) (first loops) 908 and 909, each having an opening, are serially connected via the ends thereof. An end of the loop 908 is open, while an end of the loop 909 is linearly connected with a reading unit configured to read induction current. The winding directions of the loops 908 and 909 are reversed from each other in planar view. Specifically, when the path of the signal line 905 is followed from one end to the other, or vice versa, the winding directions of the loops 908 and 909 in planar view are reversed from each other.

A GND line (first ground line) 904 corresponding to the outer conductor of the coaxial cable is formed at the surface of the upper layer substrate 901. In planar view, the GND line 904 is basically formed along the signal line 905 on the middle layer substrate 902. A plurality of slits 911a and 911b are formed in a plurality of loops (second loops) 918 and 919, respectively, of the GND line 904 to divide the GND line and expose the surface of the substrate. The GND line 904 has a width larger than that of the signal line 905. The plurality of slits 911a and 911b define a plurality of ground line parts 904a, 904b and 904c which are electrically connected to each other via first joints 904d and 904e located at positions different from those of the slits 911a and 911b. The plurality of ground line parts 904a, 904b and 904c as well as the first joints 904d and 904e are integrally formed to serve as the GND line 904.

Similarly, a GND line (second ground line) 906 corresponding to the outer conductor of the coaxial cable is also formed at the surface of the lower layer substrate 903. In planar view, the GND line 906 is basically formed along the signal line 905 on the middle layer substrate 902. A plurality of slits 921a and 921b are formed in a plurality of loops (third loops) 928 and 929, respectively, of the GND line 906 to divide the GND line and expose the surface of the substrate. The positions of the slits 921a and 921b correspond to those of the slits 911a and 911b, respectively. The GND line 906 has a width larger than that of the signal line 905. The plurality of slits 921a and 921b define a plurality of ground line parts 906a, 906b and 906c which are electrically connected to each other via second joints 906d and 906e located at positions different from those of the slits 921a and 921b. The ground line parts 906a, 906b and 906c as well as the second joints 906d and 906e are integrally formed to serve as the GND line 906.

The GND lines 904 and 906 and the signal line 905 form a strip line. An end of the signal line 905 is electrically connected to the GND lines 905 and 906 via a through hole 907. It should be appreciated that the advantages of the present invention may also be enjoyed by performing etching the substrate at portions corresponding to the slits 911a, 911b, 921a and 921b to expose the signal line 905.

The side faces of the multi-layer substrate 802 are open. If the individual layers are prepared to be sufficiently thin, the magnetic field probe 801 shown in FIG. 8 will operate in the similar manner as have been explained referring to FIG. 3B. Thus, the induction currents induced in the individual loops mutually intensify each other to enable high-sensitivity measurement even from right above the currents.

As described above, the present embodiment is configured to use the multi-layer substrate so that a considerably thin magnetic field probe can be fabricated. Thus, measurement can be performed even in a narrow space by blocking physical interference as much as possible. Also, use of an etching process can enhance the fabrication accuracy, and facilitate fabrication of plural magnetic probes having equal performance. In addition, downsizing can be easily achieved, comparing with the coaxial cable to also provide an advantage of high spatial resolution.

### Third Embodiment

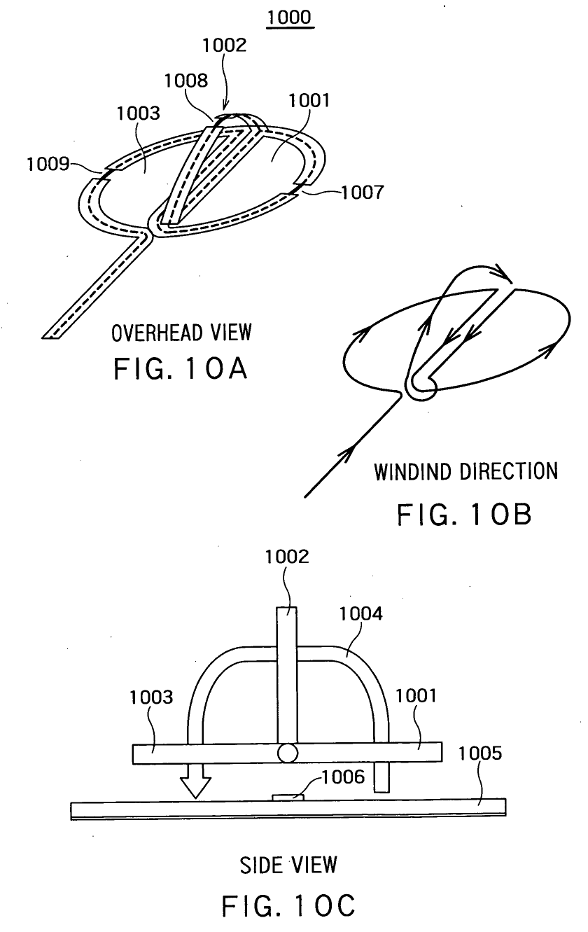

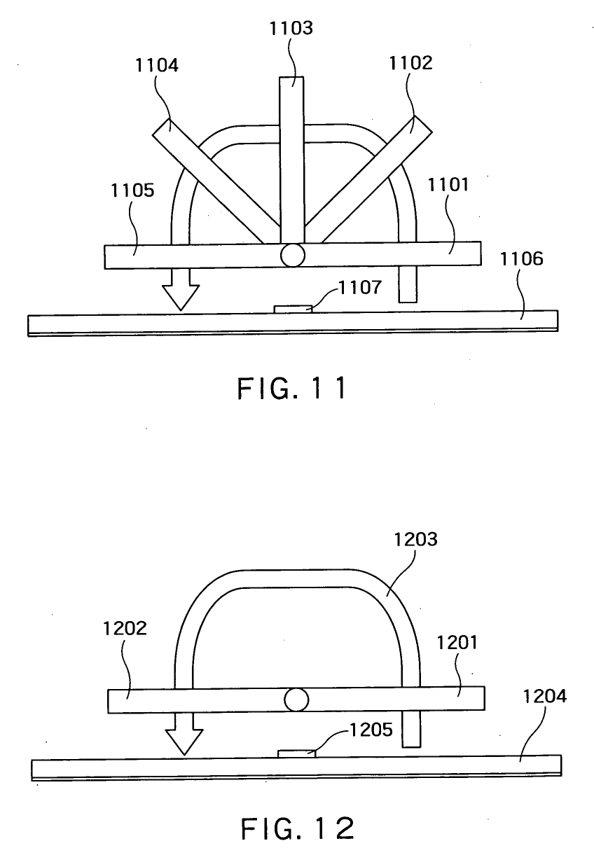

With reference to FIGS. 10A to 11, hereinafter is described a third embodiment of the present invention.

FIGS. 10A to 10C are schematic diagrams illustrating a magnetic field probe according to the third embodiment. FIG. 10A is an overhead view, FIG. 10B is an illustration showing a winding direction of a coaxial cable and FIG. 10C is a side view.

As shown in FIG. 10A, a probe 1000 of the present embodiment includes loops 1001 and 1003 residing in the same plane, as well as a loop (additional loop) 1002 residing in a plane perpendicular to the above plane. In lateral view, as in FIG. 10C, the loops 1001 to 1003 are extended in the radial direction. Slits 1007 to 1009 are formed in the loops 1001 to 1003, respectively. The winding directions of the loops 1001 to 1003 are as shown in FIG. 10B. Specifically, in lateral view, the winding directions of the loops 1001 to 1003 are all uniformly directed in the radial direction. The coaxial cable may be wound so that all the loops may be wound in the direction opposite to the radial direction. In other words, the loops may be directed so as to satisfy a right hand screw with respect to a magnetic field to be measured. Let us assume that a measurement is made for a magnetic field 1004 formed, as shown in FIG. 10C, by the current passing through a microstrip line 1006 on a substrate 1005. In this case, the way of winding as mentioned above can permit the magnetic field 1004 to pass through the loops 1001 to 1003 as shown in the figure, and permit the currents induced in the loops to mutually intensify each other, thereby realizing a high sensitive magnetic field probe.

If the loops are directed so as to satisfy a right hand screw with respect to the magnetic field to be measured, the loops may be arranged not only being horizontal or vertical but also being inclined, with respect to the surface of the substrate. In contrast to the configuration shown in FIGS. 10A to 10C, FIG. 11 illustrates an example of a magnetic field probe added with inclined loops (additional loops) 1102 and 1104 to have a total of five loops. The five loops are radially extended in lateral view. In this case as well, the winding directions of the additional loops 1102 and 1104 can be determined so that the currents induced to the individual loops can mutually intensify each other to thereby realize a high sensitive magnetic probe. Specifically, the winding directions of the five loops may all be uniformly directed, in lateral view, to the radial direction or the opposite direction thereof. As a matter of course, the loops 1102 and 1104 are also formed with slits, although not shown, which divide the outer conductor and expose the inner conductor or the inner insulator.

### Fourth Embodiment

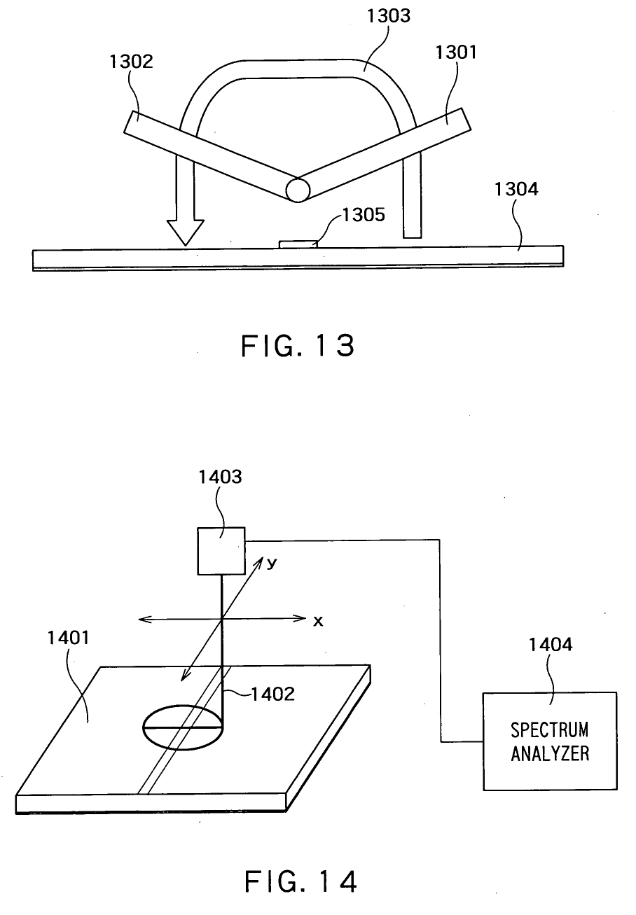

With reference to FIGS. 12 and 13, hereinafter is described a fourth embodiment of the present invention.

FIG. 12 is a side view of the magnetic field probe described in the first embodiment and illustrated in FIGS. 1A and 1B.

When a magnetic field passes the loops as shown in the figure, the sensitivity of the two loops having the same areas is maximized. However, since loops 1201 and 1202 are positioned close to a substrate 1024, the loops and the substrate 1204 mutually take the influence of the other. Accordingly, the loops are likely to give influence to the current to be measured (current of a microstrip line 1205) to deteriorate the accuracy of measurement.

FIG. 13 shows a magnetic field probe according to the fourth embodiment which is configured to suppress the above influence.

Loops 1301 and 1302 are arranged being opposed to the surface (surface to be measured) of a substrate 1304. The loops 1301 and 1302 are inclined in such a way that the distance between the loops and the surface of the substrate 1304 (distance in the direction perpendicular to the surface of the substrate 1304) will become larger as the loops extend apart from the center that lies between the loops. Thus, the influence of the loops 1301 and 1302 on the current to be measured (current of a microstrip line 1305) can be suppressed.

### Fifth Embodiment

With reference to FIGS. 14 to 16, hereinafter is described a fifth embodiment of the present invention.

FIGS. 14 to 16 illustrate current distribution measuring devices using the magnetic field probes that have been proposed as the first to fourth embodiments.

The current distribution measuring device shown in FIG. 14 includes an object 1401 to be measured, a proposed magnetic field probe 1402, a probe scanner (scanning device) 1403 and a spectrum analyzer 1404. Since the current passing through the object 1401 to be measured causes magnetic fields in the vicinity of the object 1401, the current distribution can be grasped by measuring the magnetic fields. With a conventional magnetic field probe, the magnetic fields to be observed have been minimized right above the current, as specifically described in the above section of “Related Art”. In contrast, the proposed magnetic field probe 1402 can maximize the measurement value of the magnetic fields right above the current. Therefore, the current distribution can be intuitively understood by indicating the measured values on a graph.

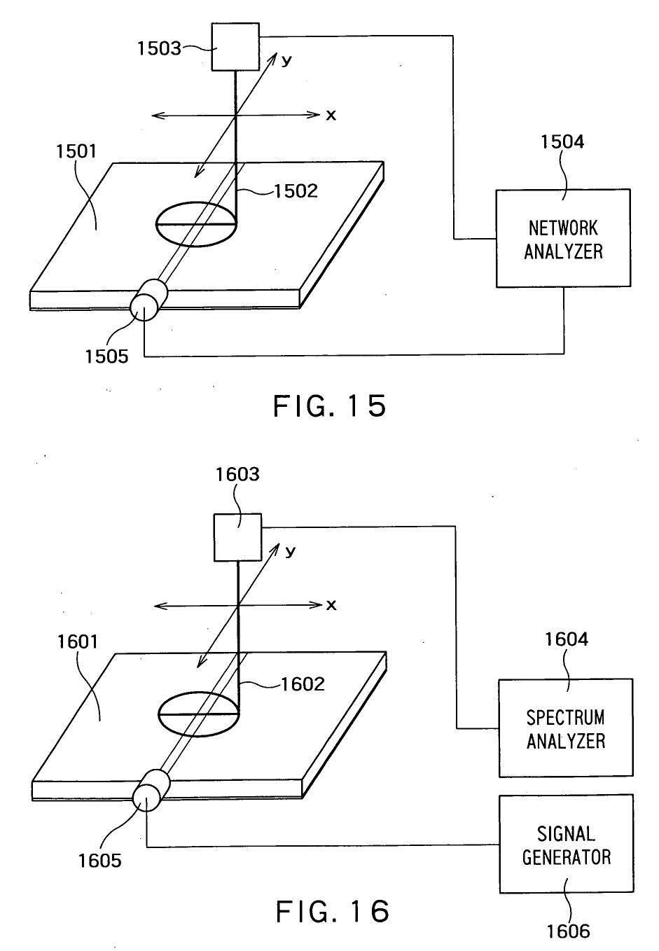

The current distribution measuring device shown in FIG. 15 has a configuration that can be favorably used for an antenna board, for example, as an object 1501 to be measured without incorporating a signal source therein. In this case, power is required to be supplied from a power supply port 1505 of the object 1501 to be measured. In this regard, in the configuration shown in FIG. 15, a network analyzer 1504 is used. The network analyzer 1504 has a port 1 connected to the power supply port 1505, and has a port 2 connected to a magnetic field probe 1502 (to an end of a coaxial cable, which is opposite to an end connected to an outer conductor part of the coaxial cable) via a probe scanner 1503. Thus, by measuring transmission characteristics S21, the current distribution can be equivalently measured.

Similarly, as shown in FIG. 16, a signal generator 1606 may be connected to a power supply port 1605 of an object 1601 to be measured, and a spectrum analyzer 1604 may be connected to a magnetic field probe 1602 via a probe scanner 1603 to thereby equivalently measure the current distribution.

### Sixth Embodiment

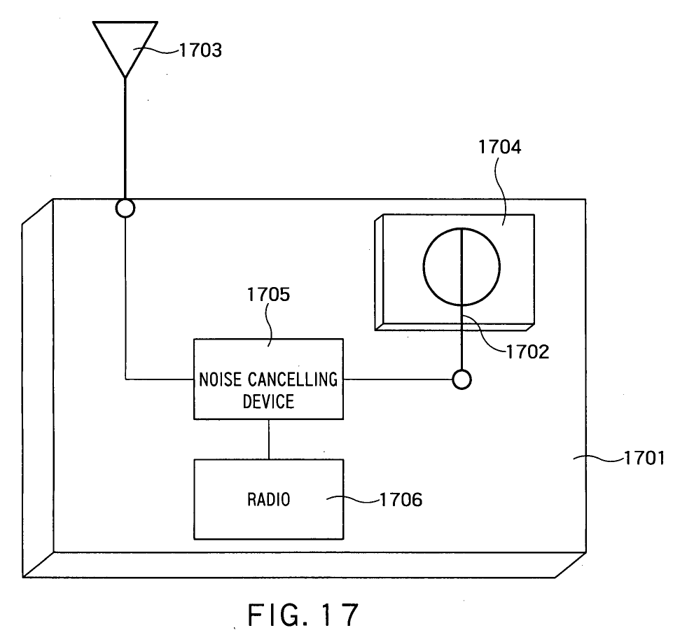

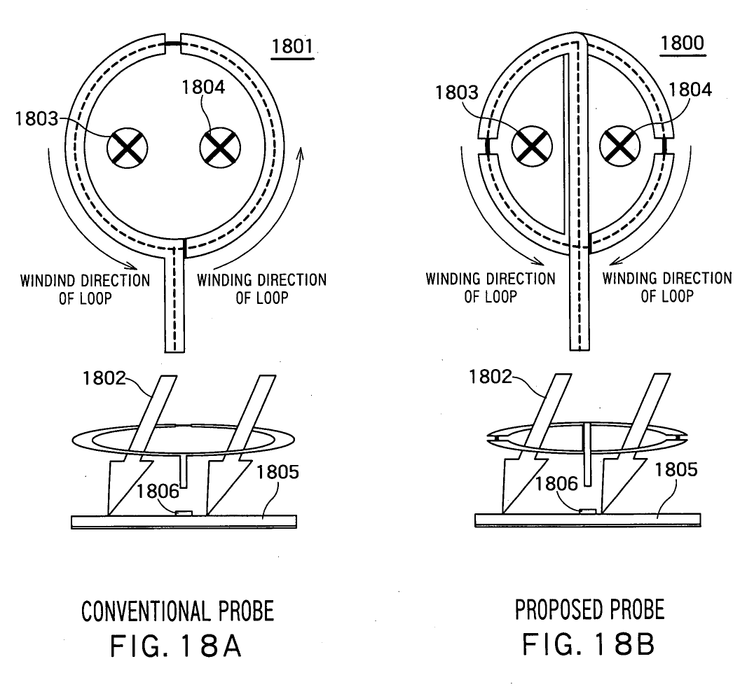

With reference to FIGS. 17 to 18B, hereinafter is described a sixth embodiment of the present invention.

FIG. 17 illustrates a radio device using the magnetic field probes that have been proposed as the first to fourth embodiments.

The radio device shown in FIG. 17 includes a circuit board 1701, a proposed magnetic field probe 1702 that picks up internal noise, an antenna 1703 that receives external signals, a noise source 1704, a noise cancelling device 1705 and a radio 1706.

First, an example of the operation of the noise cancelling device 1705 is explained. The noise cancelling device 1705 has two input ports and one output port. One input port is inputted with external (desired) signals mixed with noise and the other input port is inputted with only (undesired) noise. If there is correlation between the noises of the input ports, the noises can be cancelled by performing subtraction between the inputs. Specifically, inputs of only noise may be phase reversed, followed by addition of the both.

The performance required of the magnetic field probe 1702 for picking up the internal noise, includes receiving noise with high sensitivity, and not receiving external signals as much as possible. The reason for the latter is that, if external signals are received, the above subtraction operation may attenuate not only the noise but also the external signals. The issue that the proposed magnetic field probe 1702 can receive noise with high sensitivity has already been described with reference to FIG. 3. Here, referring to FIGS. 18A and 18B, the reason why the proposed magnetic field probe 1702 is unlikely to receive external signals is explained.

FIGS. 18A and 18B are explanatory views illustrating the difference in the operation for a magnetic field in a certain direction, between a conventional probe 1801 and a proposed probe 1800. Each of the figures shows a relationship between magnetic fields and loops in the case where the probe is located right above a line 1806 on a substrate 1805 so as to be parallel to the surface of the substrate.

Since external signals travel over a long distance sufficiently, the direction of the magnetic fields is constant. Focusing on this point, in the case of the example shown in the figures, magnetic fields 1802, 1803 and 1804 are all interlinked with the individual loops from above.

In this case, the magnetic fields interlinked with the conventional probe 1801 are all directed to the same direction, and thus the currents induced to the loops mutually intensify each other. On the other hand, in the proposed probe 1800, the winding direction of the loop with which the magnetic field 1803 is interlinked is reversed from the winding direction of the loop with which the magnetic field 1804 is interlinked. Accordingly, currents induced to the loops mutually cancel each other. For this reason, it will be understood that external signals are unlikely to be received in the proposed probe 1800. Accordingly, the proposed magnetic field probe 1702 shown in FIG. 17 can be regarded as being suitable for use as a probe for picking up internal noise. Specifically, the proposed magnetic field probe 1702 can offset the influence of the undesired magnetic fields that have traveled over a long distance to accurately estimate the desired current right beneath the probe.

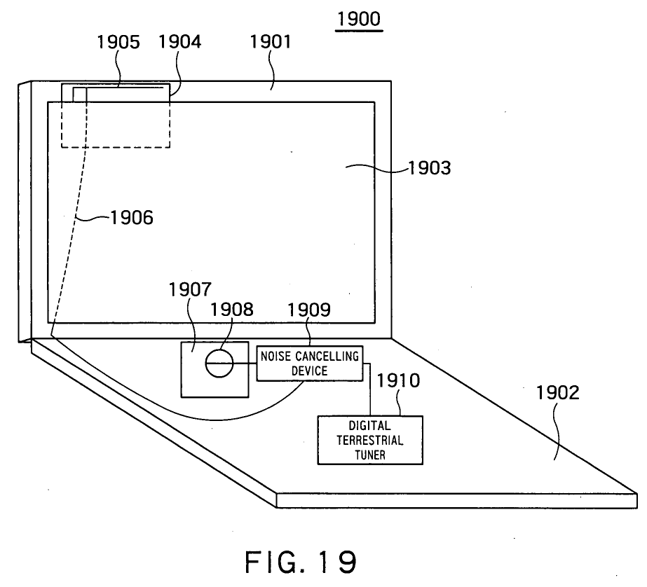

FIG. 19 shows a specific example of the radio device shown in FIGS. 18A and 18B. FIG. 19 shows a laptop computer capable of receiving/reproducing digital terrestrial television (digital terrestrial) broadcast waves.

An upper casing 1901 incorporates therein a liquid-crystal panel 1903, an antenna board 1904 and an antenna element 1905 (reverse F-shaped antenna here). A lower casing 1902 incorporates therein a noise source 1907 for digital terrestrial broadcast waves, a proposed magnetic field probe 1908, a noise cancelling device 1909 and a digital terrestrial tuner 1910. One input of the noise cancelling device 1909 is connected to the antenna board 1904 via a coaxial cable 1906, and the other input is connected to the proposed magnetic field probe 1908. An output of the noise cancelling device 1909 is connected to an input of the digital terrestrial tuner 1910.

The antenna incorporated in the laptop computer is likely to be influenced by the noise generated from an internal circuit of the computer. In particular, if the antenna board 1904 is set up in the upper casing, being conscious of the reception performance, the antenna will receive a large influence of noise that accompanies display drawing. Thus, depending on circumstances, desired signals may not be reproduced. The noise that accompanies the display drawing can be observed at a plurality of points, such as the positions where semiconductor chips in charge of drawing are located. Therefore, one of such points is treated as the noise source 1907 and the proposed magnetic field probe 1908 is located right above the point. Thus, the proposed magnetic field probe 1908 can receive the noise highly correlated with the noise that would be mixed into the reception signals of the antenna element 1905. At the same time, for the reason described above, the proposed magnetic field probe 1908 is configured so that the digital terrestrial broadcast waves are unlikely to be received.

The digital terrestrial broadcast waves mixed with noise and received by the antenna element 1905 and the noise received by the proposed magnetic field probe 1908 are inputted to the noise cancelling device 1909. The inputted data are then subjected to the subtraction process mentioned above, so that high-quality signals having high carrier-to-noise ratio (C/N ratio) can be inputted to the digital terrestrial tuner 1910. Thus, the user can enjoy comfortable television watching even in an indoor space, for example, where electrical power is weak for receiving digital terrestrial broadcast waves.

In this way, the proposed magnetic field probes according to the first to fourth embodiments have a feature that the probes can properly receive arced magnetic fields (internal noise) and that the probes cancel magnetic fields (external signals) that have traveled over a long distance and thus are unlikely to receive the same. Thus, the proposed magnetic field probes can each be utilized as a reference noise pickup probe for a noise cancelling device to improve the C/N ratio inputted to a radio device.

The magnetic field probes proposed in the first to fourth embodiments may each be used as a noise pickup probe for antennas, such as a cell-phone-incorporating antenna or an in-vehicle communication antenna, which are expected to be used in adverse noise environments.

What is claimed is:

1. A magnetic field probe comprising:
a probe body which is a coaxial cable wound to form a plurality of loop-like portions in planar view, the coaxial cable including an inner conductor, an insulator enclosing the inner conductor and an outer conductor enclosing the insulator; and
a plurality of notches each of which is formed in each of the loop-like portions so that the outer conductor is divided to expose the inner conductor or the insulator, wherein:
a plurality of outer conductor parts resulting from division by the notches are arranged to be electrically connected to each other,
an one end of the inner conductor in the coaxial cable is connected to any one of the outer conductor parts; and
winding directions of at least one of a pair of loop-like portions among the loop-like portions are reversed from each other in planar view.

2. The probe according to claim 1, wherein:
the loop-like portions are radially arranged in lateral view; and
winding directions of the loop-like portions are all directed to same direction as a radial direction in lateral view or a reverse direction from the radial direction in the lateral view.

3. The probe according to claim 1, wherein:
when the probe body is disposed such that the pair of loop-like portions are faced to a surface to be measured, each loop-like portion of the pair is inclined with respect to the surface in such a way that distances between the surface and said each loop-like portion become larger respectively as extend apart from a center between said each loop-like portion.

4. The probe according to claim 1, wherein:
when the probe body is disposed such that the pair of loop-like portions is faced to a surface to be measured, the other end of the coaxial cable is directed substantially vertical to the surface to be measured to form a vertical part; and
the loop-like portions have an asymmetric structure with respect to the vertical part of the probe body.

5. The probe according to claim 1, wherein:
a cable part starting from the one end of the coaxial cable to just before a nearest notch along the coaxial cable is a portion of one of the pair of loop-like portions;
the cable part is replaced by a metal member having substantially same thickness as the coaxial cable; and
an one end of the metal member is connected to the inner conductor in the nearest notch, and the other end of the metal member is connected to any one of the outer conductor parts.

6. A magnetic field probe comprising:
a multi-layer substrate including a lower layer substrate, a middle layer substrate and an upper layer substrate;
a signal line formed at a surface of the middle layer substrate, wherein the signal line includes a plurality of first loop-like portions each having an opening and being serially connected via an one end or both ends of each of the first loop-like portions, and at least one of a pair of loop-like portions among the first loop-like portions have winding directions which are reversed from each other in planar view when a path of the signal line is followed from one end of the signal line to the other end of the signal line, or vice versa;
a first ground line formed at a surface of the upper layer substrate so as to go along the signal line in planer view, wherein the first ground line has second loop-like portions corresponding to the first loop-like portions in planer view, each of the second loop-like portions has a first notch formed to divide the first ground line to expose a surface of the upper layer substrate, and the first ground line has a first joint which electrically connects between lines resulting from division by each first notch, via a position different from that of the first notch;
a second ground line formed at a surface of the lower layer substrate so as to go along the signal line, wherein the second ground line has third loop-like portions corresponding to the first loop-like portions in planer view, each of the third loop-like portions has a second notch to divide the second ground line to expose a surface of substrate at a position corresponding to the first notch in planer view, and the second ground line has a second joint which electrically connects between lines resulting from division by each second notch, via a position different from that of the second notch; and
a through hole formed in the multi-layer substrate which connects the one end of the signal line to the first and the second ground lines electrically.

7. A current distribution measuring device which measures current distribution on a substrate, comprising:
a magnetic field probe according to claim 1;
a scanning device configured to scan a surface of the substrate by using the magnetic field probe; and
a reading unit configured to read induction current produced at the magnetic field probe depending on magnetic fields generated in the substrate.

8. A radio device provided in an electronic device including a noise source, comprising:
an antenna configured to receive signals;
the magnetic field probe according to claim 1, which is provided for the noise source and produces induction current depending on magnetic fields generated at the noise source;
a noise cancellation unit configured to cancel noise components which have mixed into received signals of the antenna, by subtracting components of the produced induction current from the received signals; and
a signal processor configured to process the received signals after nose cancellation.
